(19) United States
(12) Patent Application Publication
(10) Pub. No.: US 2016/0348276 A1
(43) Pub. Date: Dec. 1, 2016

(54) PROCESS CHAMBER WITH REFLECTOR

(71) Applicant: Applied Materials, Inc., Santa Clara, CA (US)

(72) Inventors: Shu-Kwan LAU, Sunnyvale, CA (US); Surajit KUMAR, Sunnyvale, CA (US); Kartik SHAH, Sunnyvale, CA (US); Mehmet Tugrul SAMIR, Mountain View, CA (US)

(21) Appl. No.: 15/167,480

(22) Filed: May 27, 2016

Related U.S. Application Data
(60) Provisional application No. 62/168,670, filed on May 29, 2015.

(51) Int. Cl. C30B 25/16; C23C 16/48

(52) U.S. Cl. CPC C30B 25/165; C23C 16/482

(57) ABSTRACT

A reflector for processing a semiconductor substrate is provided. The reflector includes an annular body having an outer edge, an inner edge, and a bottom side. The bottom side includes a plurality of first surfaces and a plurality of second surfaces. Each first surface and each second surface is positioned at a different angular location around the annular body. Each first surface is a curved surface having a radius of curvature from about 1.50 inches to about 2.20 inches.

### CROSS-REFERENCE TO RELATED APPLICATIONS

This application claims priority to U.S. Provisional Patent Application Ser. No. 62/168,670, filed on May 29, 2015, which herein is incorporated by reference.

### BACKGROUND

Field

Embodiments described herein generally relate to a semiconductor process chamber. More specifically, embodiments of the disclosure relate to a semiconductor process chamber having one or more reflectors.

Description of the Related Art

In the fabrication of integrated circuits, deposition processes are used to deposit films of various materials upon semiconductor substrates. These deposition processes may take place in an enclosed process chamber. Epitaxy is a deposition process that grows a thin, ultra-pure layer, usually of silicon or germanium on a surface of a substrate. Forming an epitaxial layer on a substrate with uniform thickness across the surface of the substrate can be challenging. For example, there are often portions of the epitaxial layer, where the thickness dips or rises for an unknown reason. These variations in thickness degrade the quality of the epitaxial layer and can increase production costs. Thus, there is a need for an improved process chamber to produce epitaxial layers having a uniform thickness across the surface of the substrate.

### SUMMARY

Embodiments disclosed herein generally relate to a reflector to be used in a semiconductor process chamber. In one embodiment, a reflector for processing a semiconductor substrate is provided. The reflector includes an annular body having an outer edge, an inner edge, and a bottom side. The bottom side includes a plurality of first surfaces and a plurality of second surfaces. Each first surface and each second surface is positioned at a different angular location around the annular body. Each first surface is a curved surface having a radius of curvature from about 1.50 inches to about 2.20 inches.

In another embodiment, a reflector for processing a semiconductor substrate is provided. The reflector includes an annular body having an outer edge, an inner edge, and a bottom side. The bottom side includes 20 first surfaces and 12 second surfaces. Each first surface and each second surface is positioned at a different angular location around the annular body. Each first surface is a curved surface having a radius of curvature from about 2.02 inches to about 2.10 inches. Each second surface is disposed adjacent to, and between, two first surfaces.

In another embodiment, a process chamber is provided including a sidewall, a substrate support, and a first reflector disposed above the substrate support. The first reflector includes an annular body having an outer edge, an inner edge, and a bottom side, the bottom side including a plurality of first surfaces and a plurality of second surfaces. Each first surface and each second surface is positioned at a different angular location around the annular body. Each first surface is a curved surface having a radius of curvature from about 1.50 inches and about 2.20 inches.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a side sectional view of a process chamber, according to one embodiment of the disclosure.

FIG. 2A is a bottom perspective view of a reflector to be used in the process chamber of FIG. 1, according to one embodiment of the disclosure.

FIG. 2B is a partial side sectional view of the reflector of FIG. 2A, according to one embodiment of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a semiconductor process chamber. More specifically, embodiments of the disclosure relate to a semiconductor process chamber having one or more reflectors.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a basis plane of the chamber, for example a plane parallel to a substrate processing surface of the chamber.

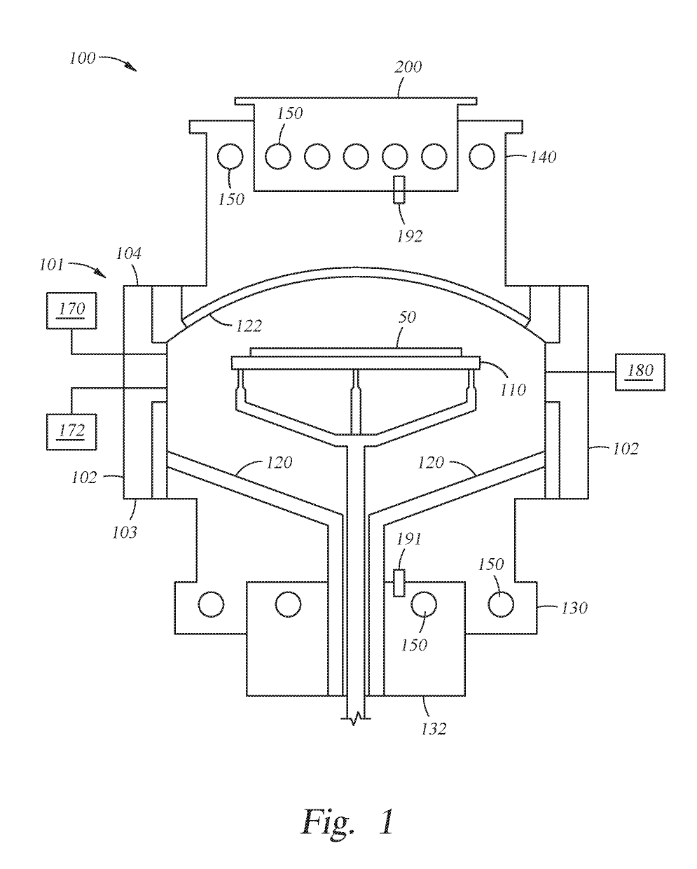

FIG. 1 is a side sectional view of a process chamber 100, according to one embodiment of the disclosure. The process chamber 100 can be used to deposit epitaxial films on a substrate 50. The process chamber 100 can operate at reduced pressures or near atmospheric pressure. The process chamber 100 includes a chamber body 101 having one or more side walls 102, a bottom 103, and a top 104 disposed on the side walls 102.

The process chamber 100 further includes a substrate support 110 disposed in the chamber body 101 to support the substrate 50 during processing. The substrate 50 on the substrate support 110 can be heated by lamps 150 disposed above and below the substrate support 110. The lamps 150 can be, for example, tungsten filament lamps. The lamps 150 below the substrate support 110 can direct radiation, such as infrared radiation, through a lower dome 120 disposed below the substrate support 110 to heat the substrate 50 and/or the substrate support 110. The lower dome 120 can be made of a transparent material, such as quartz. In some embodiments, a substrate support 110 having a ringed shape may be used. A ringed-shaped substrate support can be used to support the substrate 50 around the edges of the substrate 50, so that the bottom of the substrate 50 is directly exposed to the heat from the lamps 150. In other embodiments, the substrate support 110 is a heated susceptor to increase temperature uniformity of the substrate 50 during processing. The lamps 150 below the substrate support 110 can be installed within or adjacent to a lower outer reflector 130 and within or adjacent to a lower inner reflector 132. The lower outer reflector 130 can surround the lower inner reflector 132. The lower outer reflector 130 and the lower inner reflector 132 can be formed of aluminum and plated with a reflective material, such as gold. A lower temperature sensor 191, such as a pyrometer, can be installed in the lower inner reflector 132 to detect a temperature of the substrate support 110 or the back side of the substrate 50.

The lamps 150 above the substrate support 110 can direct radiation, such as infrared radiation, through an upper dome 122 disposed above the substrate support 110. The upper dome 122 can be made of a transparent material, such as quartz. The lamps 150 above the substrate support 110 can be installed within or adjacent to an upper inner reflector 200 (a first reflector) and within or adjacent to an upper outer reflector 140 (a second reflector). The upper outer reflector 140 can surround the upper inner reflector 200. The upper outer reflector 140 and the upper inner reflector 200 can be formed of aluminum and plated with a reflective material, such as gold. An upper temperature sensor 192, such as a pyrometer, can be installed in or adjacent to the upper inner reflector 200 to detect a temperature of the substrate 50 during processing. Although FIG. 1 shows the same lamp 150 installed within the reflectors 130, 132, 140, 200, different types and/or sizes of lamps may be installed within or adjacent to each of these reflectors 130, 132, 140, 200. Furthermore, different types or sizes of lamps may installed within or adjacent to one of the reflectors.

The process chamber 100 can be coupled to one or more process gas sources 170 that can supply the process gases used in the epitaxial depositions. The process chamber 100 can further be coupled to an exhaust device 180, such as a vacuum pump. In some embodiments, the process gases can be supplied on one side (e.g., the left side of FIG. 1) of the process chamber 100 and gases may be exhausted from the process chamber on an opposing side (e.g., the right side of FIG. 1) to create a cross flow of process gases above the substrate 50. The process chamber 100 may also be coupled to a purge gas source 172.

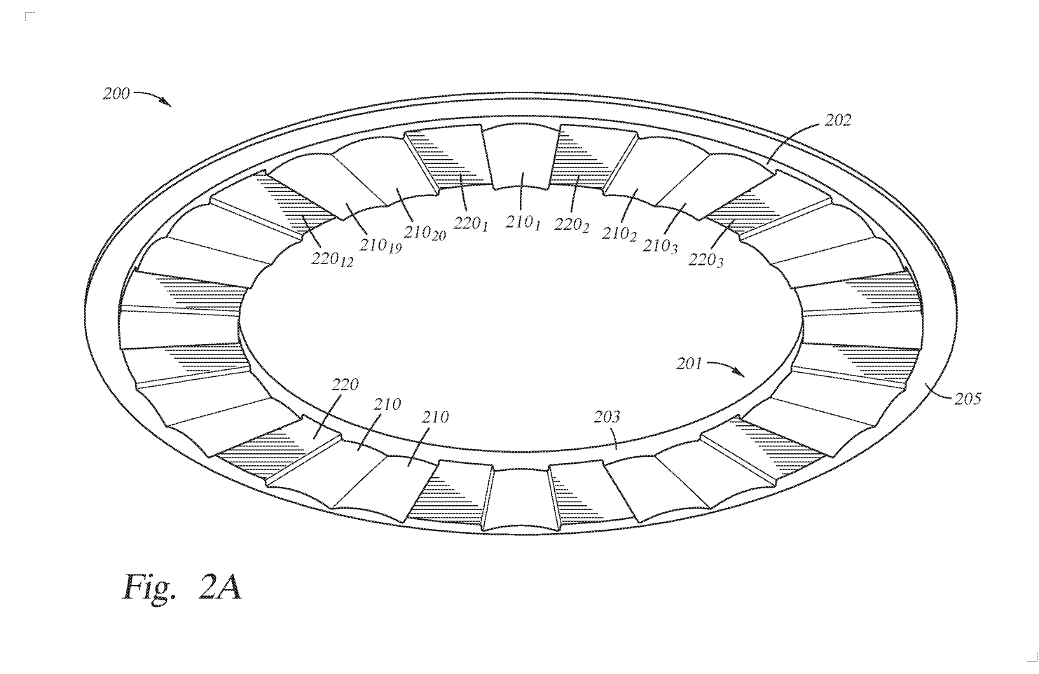

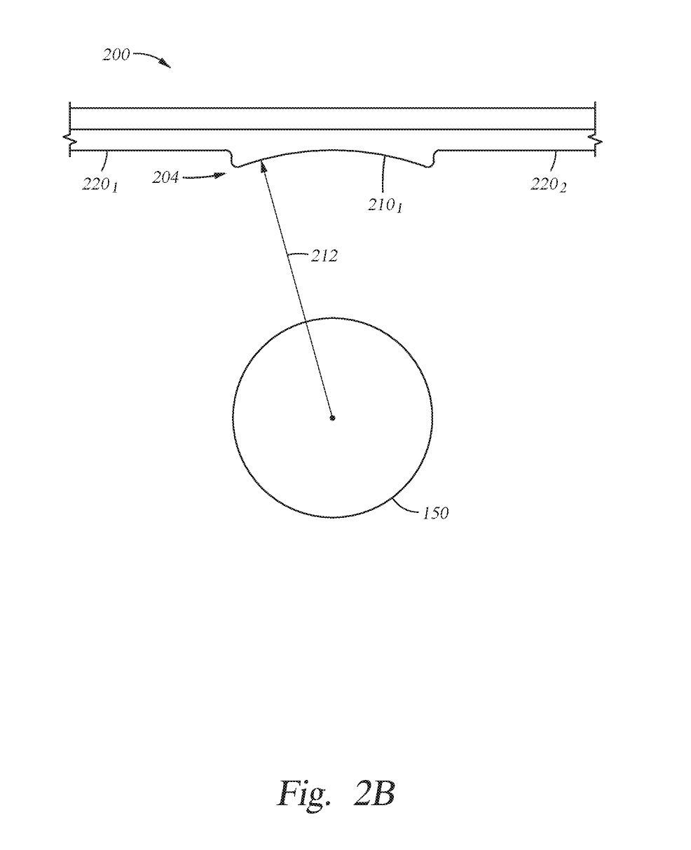

FIG. 2A is a bottom view of the upper inner reflector 200 of FIG. 1, according to one embodiment of the disclosure. FIG. 2B is a partial side sectional view of the upper inner reflector 200 of FIG. 2A, according to one embodiment of the disclosure. The upper inner reflector 200 includes an annular body 201 having an outer edge 202, an inner edge 203, and a bottom side 204 (see FIG. 2B). The upper inner reflector 200 further includes an outer rim 205 disposed above and outward of the bottom side 204 of the annular body 201. In some embodiments, the outer rim 205 can be used to fasten the upper inner reflector 200 during installation. The bottom side 204 includes a plurality of first reflecting surfaces 210 (first surfaces) and a plurality of second reflecting surfaces 220 (second surfaces). The first reflecting surfaces 210 and the second reflecting surfaces 220 can be formed of a highly reflective material, such as gold to reflect the radiation from the lamps 150 in the process chamber 100. The second reflecting surfaces 220 are hatched to further distinguish the second reflecting surfaces 220 from the first reflecting surfaces 210. Each first reflecting surface 210 and each second reflecting surface 220 is positioned at a different angular location around the annular body 201. In some embodiments, the upper inner reflector 200 includes from about 16 to about 24 first reflecting surfaces 210, such as about 20 first reflecting surfaces 210. FIG. 2A is shown with 20 first reflecting surfaces 210 (see 210₂₀). In some embodiments, the upper inner reflector 200 includes from about 8 to 16 second reflecting surfaces 220, such as about 12 second reflecting surfaces 220. FIG. 2A is shown with 12 second reflecting surfaces 220 (see 220₁₂).

The partial side sectional view of FIG. 2B is a view of the reflecting surfaces 220₁, 210₁, and 220₂ at the top center of FIG. 2A. A lamp 150 is also included in FIG. 2B to show the location of the lamps 150 relative to the first reflecting surfaces 210. The lamps 150 are disposed beneath the first reflecting surfaces 210 in the process chamber 100 (i.e., between the first reflecting surfaces 210 and the substrate support 110). In some embodiments, the lamps 150 are not placed between the second reflecting surfaces 220 and the substrate support 110. For example, if the lamps 150 are only placed beneath the first reflecting surfaces 210, then 20 lamps 150 would be placed beneath the upper inner reflector 200 that includes 20 first reflecting surfaces 210.

The plurality of first reflecting surfaces 210 and the plurality of second reflecting surfaces 220 can be disposed around the annular body 201 in a circular array. One of the first reflecting surfaces 210 is disposed one position before and one position after each second reflecting surface 220 in the circular array. The circular array can include one or more instances in which two or more first reflecting surfaces are arranged in a row. For example, the circular array of the upper inner reflector 200 includes eight instances of two first reflecting surfaces 210 in a row. Furthermore, the circular array includes four instances in which one of the second reflecting surfaces 220 is disposed one position before and one position after one of the first reflecting surfaces 210.

Each first reflecting surface 210 is a curved surface having a radius of curvature 212 from about 1.50 inches to about 2.20 inches, such as from about 2.02 inches to about 2.10 inches, such as about 2.06 inches. On the other hand, each second reflecting surface 220 is substantially flat. In some embodiments, each first reflecting surface 210 has a cylindrical shape extending in a direction from the outer edge 202 towards the inner edge 203 of the reflector 200. In other embodiments, each first reflecting surface has a frustoconical shape extending in a direction from the outer edge 202 towards the inner edge 203 of the reflector 200. In embodiments using a frustoconical shape, the radius of curvature can decrease in the direction from the outer edge 202 towards the inner edge 203 of the reflector.

The inventors of the present application observed nonuniformities in the thickness of epitaxial layers formed on 300 mm substrates in a process chamber including the components shown in FIG. 1. These nonuniformities occurred at one or more radial locations of the substrate. Epitaxial layers having a nonuniform thickness can reduce product quality and lead to waste if the nonuniformity is substantial. Upon reviewing some differences between a number of process chambers, the inventors noticed that some of the chambers included different upper inner reflectors. The upper inner reflectors of these process chambers included different first reflecting surfaces corresponding to the first reflecting surfaces 210 described above. The inventors noticed that the degree of the thickness nonuniformity changed when the radius of these first reflecting surfaces changed. It was not previously recognized that changing the radius of a reflecting surface on an upper inner reflector of a process chamber could achieve the result of removing nonuniformities in the thickness of an epitaxial layer formed in that process chamber.

After discovering that the thickness nonuniformities could be removed by changing the radius defining the first reflecting surfaces, the inventors then determined that a radius defining the curved surface of the first reflecting surfaces from about 1.50 inches to about 2.20 inches, such as a radius from about 2.02 inches to about 2.10 inches, such as a radius of about 2.06 inches provided the best results for removing the nonuniformities in the thickness in the epitaxial layers formed in the chambers used to process 300 mm substrates. Removing these thickness nonuniformities can improve product quality and reduce waste.

While the foregoing is directed to embodiments of the present disclosure, other and further embodiments of the disclosure may be devised without departing from the basic scope thereof, and the scope thereof is determined by the claims that follow.

1. A reflector for processing a semiconductor substrate comprising:
an annular body having an outer edge, an inner edge, and a bottom side, the bottom side including a plurality of first surfaces and a plurality of second surfaces, wherein
each first surface and each second surface is positioned at a different angular location around the annular body; and
each first surface is a curved surface having a radius of curvature from about 1.50 inches to about 2.20 inches.

2. The reflector of claim 1, wherein the radius of curvature is from about 2.02 inches to about 2.10 inches.

3. The reflector of claim 1, wherein the bottom side includes 20 first surfaces and 12 second surfaces.

4. The reflector of claim 1, wherein the first reflecting surfaces are formed of gold.

5. The reflector of claim 1, wherein each first surface has a cylindrical shape extending in a direction from the outer edge towards the inner edge of the reflector.

6. The reflector of claim 1, wherein the plurality of first surfaces and the plurality of second surfaces are disposed in a circular array, wherein each second surface is disposed adjacent to, and between, two first surfaces in the circular array.

7. The reflector of claim 6, wherein the plurality of first surfaces includes four pairs of first surfaces, and each pair of first surfaces consists of two first surfaces that share an edge.

8. The reflector of claim 7, wherein the circular array includes at least one second surface adjacent to, and between, consecutive pairs of first surfaces.

9. The reflector of claim 1, wherein each second surface is substantially flat.

10. A reflector for processing a semiconductor substrate comprising:
an annular body having an outer edge, an inner edge, and a bottom side, the bottom side including 20 first surfaces and 12 second surfaces, wherein
each first surface and each second surface is positioned at a different angular location around the annular body;
each first surface is a curved surface having a radius of curvature from about 2.02 inches to about 2.10 inches; and
each second surface is disposed adjacent to, and between, two first surfaces.

11. A process chamber comprising:
a sidewall;
a substrate support;
a first reflector disposed above the substrate support, the first reflector comprising:
an annular body having an outer edge, an inner edge, and a bottom side, the bottom side including a plurality of first surfaces and a plurality of second surfaces, wherein
each first surface and each second surface is positioned at a different angular location around the annular body; and
each first surface is a curved surface having a radius of curvature from about 1.50 inches and about 2.20 inches.

12. The process chamber of claim 11, wherein the radius of curvature is from about 2.02 inches to about 2.10 inches.

13. The process chamber of claim 12, wherein the bottom side of the reflector includes 20 first surfaces and 12 second surfaces.

14. The process chamber of claim 11, wherein a lamp is disposed between each first surface and the substrate support.

15. The process chamber of claim 11, wherein the reflector further comprises an outer rim disposed above and outward of the bottom side of the annular body.

16. The process chamber of claim 13, wherein the plurality of first surfaces and the plurality of second surfaces of the reflector are disposed in a circular array, wherein each second surface is disposed adjacent to, and between, two first surfaces.

17. The process chamber of claim 16, wherein the circular array includes four pairs of first surfaces, and each pair of first surfaces consists of two first surfaces that share an edge.

18. The process chamber of claim 17, wherein the circular array includes four structures, each structure comprising a first surface disposed adjacent to, and between, two second surfaces.

19. The process chamber of claim 11, wherein each second surface of the reflector is substantially flat.

20. The process chamber of claim 11, further comprising a second reflector surrounding the first reflector.
